(19) United States
(12) Patent Application Publication
(10) Pub. No.: US 2026/0333652 A1
(43) Pub. Date: Oct. 22, 2026

(54) ABNORMALITY MANAGEMENT DEVICE, COMPONENT MOUNTING SYSTEM, AND ABNORMALITY REPORTING DEVICE

(71) Applicant: FUJI CORPORATION, Chiryu (JP)

(72) Inventor: Kohei ISHIKAWA, Hekinan-shi (JP)

(73) Assignee: FUJI CORPORATION, Chiryu (JP)

(21) Appl. No.: 19/115,839

(22) PCT Filed: Nov. 4, 2022
(86) PCT No.: PCT/JP2022/041230

§ 371 Date: Mar. 27, 2025

(51) Int. Cl. H05K 13/08

(52) U.S. Cl. CPC H05K 13/08

(57) ABSTRACT

An abnormality management device manages includes an abnormality information generation section that generates first abnormality information indicating that an abnormality has occurred in a specific component supply device, and second abnormality information indicating that an abnormality has occurred at a specific installation position; an abnormality information storage section configured to store the first abnormality information and the second abnormality information; and an abnormality information deletion section that when first work for resolving the abnormality is performed on the specific component supply device in which the abnormality has occurred, delete the first abnormality information generated by the abnormality information generation section from the abnormality information storage section, and when second work for resolving the abnormality is performed at the specific installation position where the abnormality has occurred, delete the second abnormality information generated by the abnormality information generation section from the abnormality information storage section.

### TECHNICAL FIELD

The present disclosure relates to a technique for managing abnormalities of a component mounter for mounting a component on a board.

### BACKGROUND ART

Patent Literature 1 discloses a component mounter provided with a component supply section including multiple tape feeders. The component mounter mounts a component on a board by a suction nozzle from the tape feeder. The component mounter stores the number of pickup errors that have occurred during mounting, and executes a pickup error handling process when the number of pickup errors exceeds a predetermined number. When the pickup error is not resolved by the pickup error handling process, the component mounter executes an error report. This enables a worker to manually restore the component mounter.

### CITATION LIST

### Patent Literature

Patent Literature 1: JP-A-2015-211054

### BRIEF SUMMARY

### Technical Problem

When restoring a tape feeder in which a pickup error has occurred, the worker removes the tape feeder from the component supply section. When the removed tape feeder is a cause of the pickup error or the like, another new tape feeder is installed in the component supply section. Accordingly, the pickup error in the component mounter is resolved, and the component mounter can normally mount the component. On the other hand, for the tape feeder that caused the pickup error, restoration work is required to resolve the cause of the pickup error. However, in the component mounter of Patent Literature 1, information on the tape feeder in which the pickup error has occurred (for example, information indicating that the restoration work is required) is not managed. Therefore, even when the restoration work is required for the tape feeder, for example, there is a concern that the tape feeder is installed in another component supply section without performing the restoration work. In this case, the pickup error may occur again in the component mounter in which the tape feeder is installed. The present description provides a technique capable of reducing the occurrence of the abnormalities in the component mounter.

### Solution to Problem

An abnormality management device disclosed in the present description manages abnormalities occurring in a component mounter including multiple component supply devices and multiple installation positions where the multiple component supply devices are detachably attached. The abnormality management device includes: an abnormality information generation section configured to, when a specific abnormality has occurred in the component mounter, generate first abnormality information indicating that an abnormality has occurred in a specific component supply device that is a component supply device related to the specific abnormality, and second abnormality information indicating that an abnormality has occurred at a specific installation position where the specific component supply device has been attached; an abnormality information storage section configured to store the first abnormality information and the second abnormality information generated by the abnormality information generation section; and an abnormality information deletion section. The abnormality information deletion section is configured to, when first work for resolving the abnormality is performed on the specific component supply device in which the abnormality has occurred, delete the first abnormality information generated by the abnormality information generation section from the abnormality information storage section, and when second work for resolving the abnormality is performed at the specific installation position where the abnormality has occurred, delete the second abnormality information generated by the abnormality information generation section from the abnormality information storage section.

The abnormality management device stores the first abnormality information indicating that an abnormality has occurred in a specific component supply device and the second abnormality information indicating that an abnormality has occurred at a specific installation position where the specific component supply device has been attached. Further, the abnormality management device deletes the first abnormality information when the first work is performed on the specific component supply device, and deletes the second abnormality information when the second work is performed at the specific installation position. The abnormality management device individually manages the first abnormality information related to an abnormality in the specific component supply device and the second abnormality information related to an abnormality at the specific installation position. Therefore, for example, the abnormality management device can prevent the specific component supply device whose first abnormality information is stored from being attached to another installation position. As a result, the abnormality management device can reduce the occurrence of the abnormalities in the component mounter.

The present description discloses a component mounting system. The component mounting system includes: multiple component supply devices; multiple component mounters including multiple installation positions where the multiple component supply devices are detachably attached; and the above abnormality management device configured to manage the abnormalities occurring in the multiple component mounters.

Further, the present description discloses an abnormality reporting device. The abnormality reporting device reports abnormalities occurring in a component mounter including multiple component supply devices and multiple installation positions where the multiple component supply devices are detachably attached. The abnormality reporting device includes: an abnormality information generation section configured to, when a specific abnormality related to any of the component supply devices has occurred in the component mounter, generate first abnormality information indicating that an abnormality has occurred in a specific component supply device that is a component supply device related to the specific abnormality and second abnormality information indicating that an abnormality has occurred at a specific installation position where the specific component supply device is attached; and an abnormality information reporting section configured to report two pieces of abnormality information of the generated first abnormality information and second abnormality information to a worker.

### BRIEF DESCRIPTION OF DRAWINGS

FIG. 1 is a view illustrating a schematic configuration of a component mounting system according to an example.

FIG. 2 is a view illustrating a schematic configuration of a component mounter.

FIG. 3 is a cross-sectional view taken along line III-III of FIG. 2.

FIG. 4 is a block diagram illustrating configurations of a control device of the component mounter and a management device.

FIG. 5 is a flowchart of abnormality reporting processing executed by the management device.

FIG. 6 is a diagram illustrating an example of an abnormality reporting screen.

FIG. 7 is a diagram illustrating another example of the abnormality reporting screen.

FIG. 8 is a diagram illustrating still another example of the abnormality reporting screen.

### DESCRIPTION OF EMBODIMENTS

Main features of an example described below are listed. Technical elements described below are independent technical elements, respectively, exhibit technical usefulness independently or in various combinations, and are not limited to the combinations disclosed in the claims as originally filed.

(Feature 1) The abnormality management device may further include an abnormality information reporting section configured to, when at least one of the first abnormality information and the second abnormality information is stored in the abnormality information storage section, report at least one of the first abnormality information and the second abnormality information stored in the abnormality information storage section to a worker.

With such a configuration, the abnormality management device can cause the worker to recognize that an abnormality has occurred in at least one of the specific component supply device and the specific installation position.

(Feature 2) The deletion of the first abnormality information by the abnormality information deletion section may be performed by deleting the first abnormality information stored in the abnormality information storage section from the abnormality information storage section. In this case, the deletion of the second abnormality information by the abnormality information deletion section may be performed by deleting the second abnormality information stored in the abnormality information storage section from the abnormality information storage section.

(Feature 3) The second work may include removing the specific component supply device from the specific installation position where the specific abnormality has occurred, and attaching a new component supply device to the specific installation position after the specific component supply device is removed from the specific installation position.

With such a configuration, the second abnormality information can be reliably and appropriately deleted as compared with a configuration in which the worker deletes the second abnormality information.

(Feature 4) The abnormality management device may further include an input section configured to receive that the first work has been performed. In this case, the abnormality information deletion section may delete the first abnormality information generated by the abnormality information generation section when the input section receives an input indicating that the first work is to be performed.

With such a configuration, the first abnormality information can be appropriately deleted as compared with a configuration in which the worker deletes the first abnormality information.

(Feature 5) The first abnormality information may include first identification information for identifying the specific component supply device in which the specific abnormality has occurred. In this case, the second abnormality information may include second identification information for identifying the specific installation position where the specific abnormality has occurred.

With such a configuration, the abnormality management device can specify the specific component supply device by the first identification information and specify the specific installation position by the second identification information.

### EXAMPLE

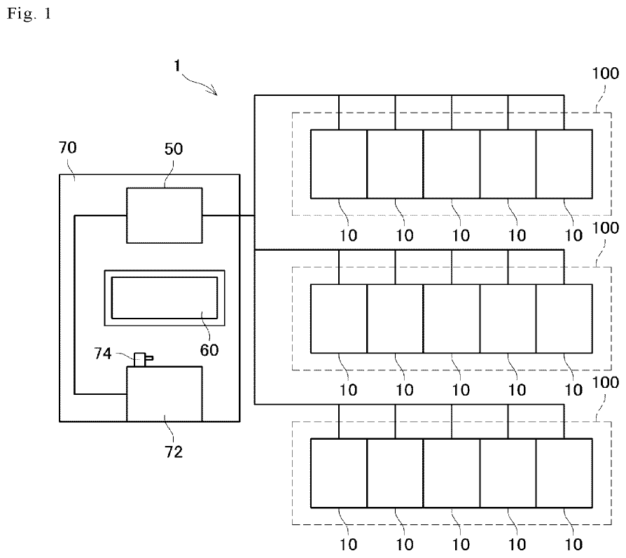

Component mounting system 1 illustrated in FIG. 1 is a system that manufactures a circuit board by mounting electronic components on a board. Component mounting system 1 includes management device 50 and multiple component mounting lines 100. Each of multiple component mounting lines 100 includes multiple component mounters 10. Each of multiple component mounters 10 is communicably connected to management device 50. Management device 50 manages multiple component mounting lines 100. That is, management device 50 manages component mounters 10 in multiple component mounting lines 100. In component mounting system 1 of the present example, each of three component mounting lines 100 includes five component mounters 10. Therefore, management device 50 manages 15 component mounters 10. The number of component mounters 10 provided in one component mounting line 100 is not limited to the above, and the number of component mounting lines 100 managed by management device 50 is also not limited to the above.

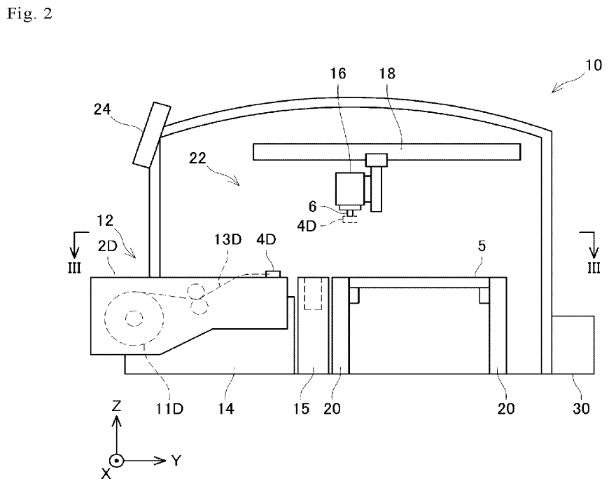

Management device 50 is provided in kitting space 70. Kitting space 70 is a space for performing maintenance work of various components constituting each component mounter 10 of component mounting system 1. Kitting space 70 includes display 60 and kitting stand 72. Display 60 reports various information on component mounting system 1 to a worker in kitting space 70. Kitting stand 72 is, for example, a jig for setting tape feeder 2D (see FIG. 2) described later, and includes connector 74 connected to tape feeder 2D.

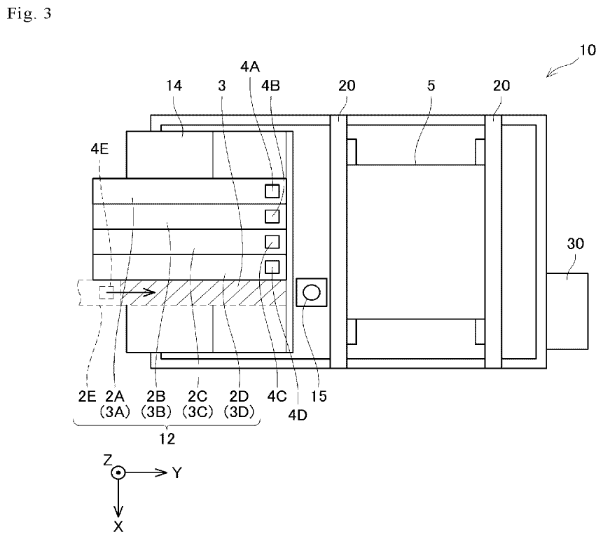

The structure of component mounter 10 will be described with reference to FIGS. 2 and 3. Component mounter 10 includes component mounting section 22, interface device 24, and control device 30. Component mounter 10 mounts an electronic component (for example, 4D) on circuit board 5.

Component mounting section 22 includes feeder unit 12, feeder holding section 14, imaging device 15, mounting head 16, head moving device 18, and board conveyor 20. As illustrated in FIG. 3, feeder unit 12 includes multiple tape feeders 2A to 2D. Tape feeder 2A accommodates electronic component 4A. Similarly, tape feeders 2B to 2D accommodate electronic components 4B to 4D, respectively. Tape feeders 2A to 2E have the same configuration. Hereinafter, the tape feeder is simply referred to as a “feeder”.

As illustrated in FIG. 2, for example, feeder 2D includes reel 11D detachably attached to a main body. Reel 11D includes long tape 13D. Tape 13D accommodates multiple electronic components 4D. When tape 13D is fed out from reel 11D in the +Y direction, electronic components 4D move toward the tip end portion of tape feeder 2D.

Feeder holding section 14 includes multiple slots 3A to 3E. Feeder 2A is attached to slot 3A. Similarly, feeders 2B to 2D are attached to slots 3B to 3D, respectively. Feeders 2A to 2E are detachable from slots 3A to 3E, respectively. For example, as illustrated in FIG. 3, feeder 2E accommodating electronic component 4E is attached to slot 3E, from which the feeder has been removed, in the +Y direction.

Mounting head 16 detachably holds one or multiple suction nozzles 6. Suction nozzle 6 picks up electronic components 4A to 4E. Head moving device 18 moves mounting head 16 with respect to each of feeders 2A to 2E and circuit board 5. Accordingly, for example, electronic component 4D is picked up from feeder 2D of multiple feeders 2A to 2E by suction nozzle 6, and electronic component 4D is mounted on circuit board 5 at a position determined in advance. Board conveyor 20 conveys in, supports, and conveys out circuit board 5.

Imaging device 15 includes a camera. Imaging device 15 captures images of electronic components 4A to 4D picked up by suction nozzle 6 from below by the camera. Imaging device 15 transmits the captured images of electronic components 4A to 4D to control device 30.

Interface device 24 is a device that provides the worker with various information on component mounter 10 and is a device that receives instructions and information from the worker. In the present example, interface device 24 is a touch panel. However, interface device 24 may, for example, include a display and a keyboard or a mouse.

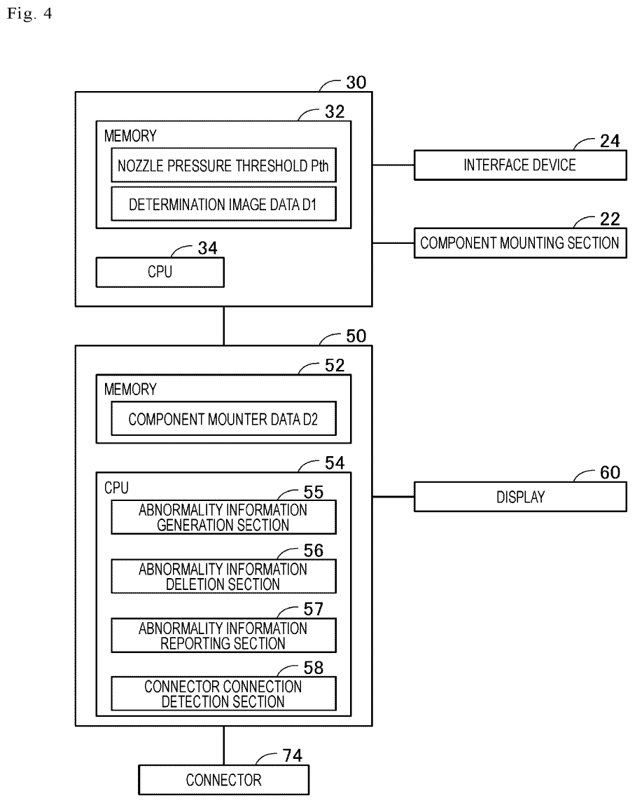

With reference to FIG. 4, a configuration of control device 30 of component mounter 10 and management device 50 will be described. Control device 30 of component mounter 10 includes a computer including memory 32 and CPU 34. Control device 30 is communicably connected to interface device 24 and component mounting section 22. Memory 32 stores nozzle pressure threshold Pth and determination image data D1. Nozzle pressure threshold Pth is a pressure threshold for determining whether suction nozzle 6 properly holds electronic components 4A to 4D. Determination image data D1 is an image (so-called master data) for verifying whether the orientations of electronic components 4A to 4D picked up by suction nozzle 6 are proper. Memory 32 further stores a production program in advance. CPU 34 controls component mounting section 22 according to the production program in memory 32. Component mounting section 22 mounts electronic components 4A to 4D on circuit board 5 at positions according to the production program, in order specified by the production program.

CPU 34 of control device 30 detects whether an abnormality has occurred when component mounting section 22 mounts electronic components 4A to 4D on circuit board 5. For example, CPU 34 acquires the suction pressure of suction nozzle 6 while suction nozzle 6 is picking up electronic components 4A to 4D. CPU 34 compares the acquired suction pressure with nozzle pressure threshold Pth. When the acquired suction pressure falls below nozzle pressure threshold Pth, CPU 34 determines that suction nozzle 6 is not holding electronic components 4A to 4D in proper orientation. In this case, CPU 34 transmits an abnormality occurrence signal indicating that an abnormality has occurred in component mounter 10 to management device 50. The abnormality occurrence signal includes a mounter ID, a feeder ID, a reel ID, and a slot ID. The mounter ID is information for identifying component mounter 10 in which an abnormality has occurred. The feeder ID is information for identifying a feeder (for example, feeder 2D) that has supplied an electronic component (for example, electronic component 4D) that is not held in proper orientation. The reel ID is information for identifying a reel (for example, reel 11D) accommodating an electronic component (for example, electronic component 4D). The slot ID is information for identifying a slot (for example, slot 3D) to which the feeder is attached.

CPU 34 of control device 30 compares the images of electronic components 4A to 4D acquired from imaging device 15 with determination image data D1. When the images of electronic components 4A to 4D are similar to the image shown by determination image data D1 by more than a predetermined ratio, CPU 34 determines that electronic components 4A to 4D are held in proper orientation by suction nozzle 6. When the images of electronic components 4A to 4D are not similar to the image shown by determination image data D1 by more than a predetermined ratio, CPU 34 determines that suction nozzle 6 is not holding electronic components 4A to 4D in proper orientation. In this case, CPU 34 transmits the above-described abnormality occurrence signal to management device 50. In a modification, component mounter 10 need not include imaging device 15. In this case, CPU 34 may determine whether the orientations of electronic components 4A to 4D are proper only by the suction pressure of suction nozzle 6. In another modification, imaging device 15 may include a camera attached to mounting head 16. In this case, CPU 34 may capture an image of the side surface of the electronic components picked up by suction nozzle 6 using the camera, and based on the image, determine whether electronic components 4A to 4D are properly picked up.

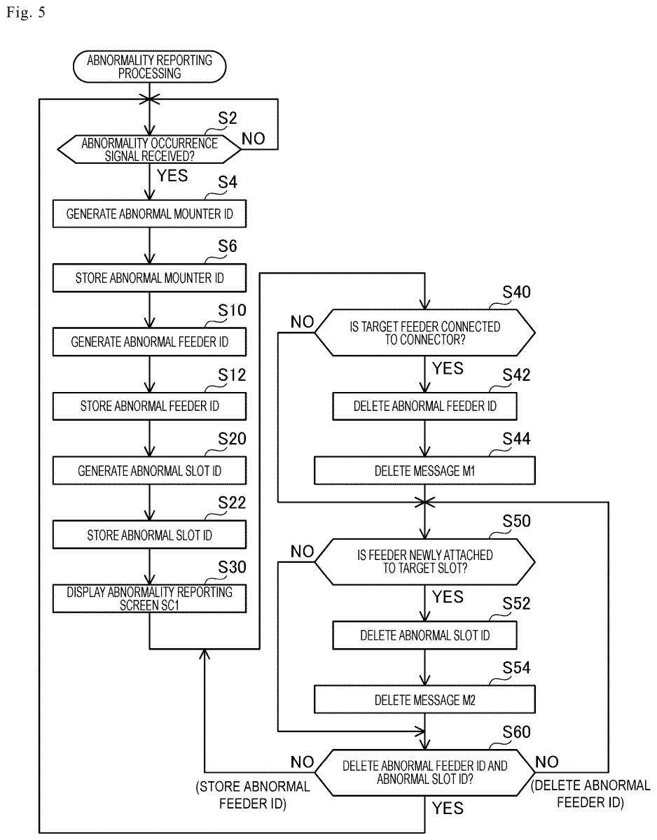

Similarly to control device 30, management device 50 also includes a computer including memory 52 and CPU 54. Management device 50 is communicably connected to control device 30, display 60, and connector 74. CPU 54 of management device 50 executes various types of processing according to a program stored in memory 52. For example, CPU 54 of management device 50 functions as abnormality information generation section 55, abnormality information deletion section 56, abnormality information reporting section 57, and connector connection detection section 58. Details of the processing executed by CPU 54 will be described later with reference to FIG. 5.

Component mounter data D2 is stored in memory 52 of management device 50. Component mounter data D2 includes a mounter ID of each component mounter 10, a feeder ID of each feeder 2 attached to each component mounter 10, a reel ID of reel 110 installed on each feeder 2, and a component ID for identifying electronic components 4 accommodated in each reel 110. The pieces of information of component mounter data D2 are associated with each other.

The abnormality reporting processing executed by CPU 54 of management device 50 will be described with reference to FIG. 5. The processing of FIG. 5 is started using the power supply of component mounting system 1 being turned on as a trigger. CPU 54 repeats the processing of FIG. 5 while component mounting system 1 is operating.

In S2, CPU 54 monitors reception of the above-described abnormality occurrence signal from control device 30 of any component mounter 10 of component mounting system 1. CPU 54 repeats the process of S2 until the abnormality occurrence signal is received from control device 30.

In S4, CPU 54 generates an abnormal mounter ID using the mounter ID included in the abnormality occurrence signal received from control device 30 of component mounter 10 in S2. The abnormal mounter ID is information for identifying component mounter 10 that has transmitted the abnormality occurrence signal. Hereinafter, the component mounter in which an abnormality has occurred is referred to as a “target component mounter”.

In S6, CPU 54 stores the generated abnormal mounter ID in memory 52.

Next, in S10, CPU 54 generates an abnormal feeder ID using the feeder ID included in the abnormality occurrence signal received from control device 30 of component mounter 10. The abnormal feeder ID includes the feeder ID for identifying the feeder in which an abnormality has occurred. Hereinafter, the feeder (for example, feeder 2D) in which an abnormality has occurred is referred to as a “target feeder”.

In S12, CPU 54 stores the generated abnormal feeder ID in memory 52.

In S20, CPU 54 generates an abnormal slot ID using the slot ID included in the abnormality occurrence signal received from control device 30 of component mounter 10 in S2. The abnormal slot ID includes the slot ID of the slot (for example, slot 3D) to which the target feeder is attached. Hereinafter, the slot to which the target feeder is attached is referred to as a “target slot”.

In S22, CPU 54 stores the generated abnormal slot ID in memory 52.

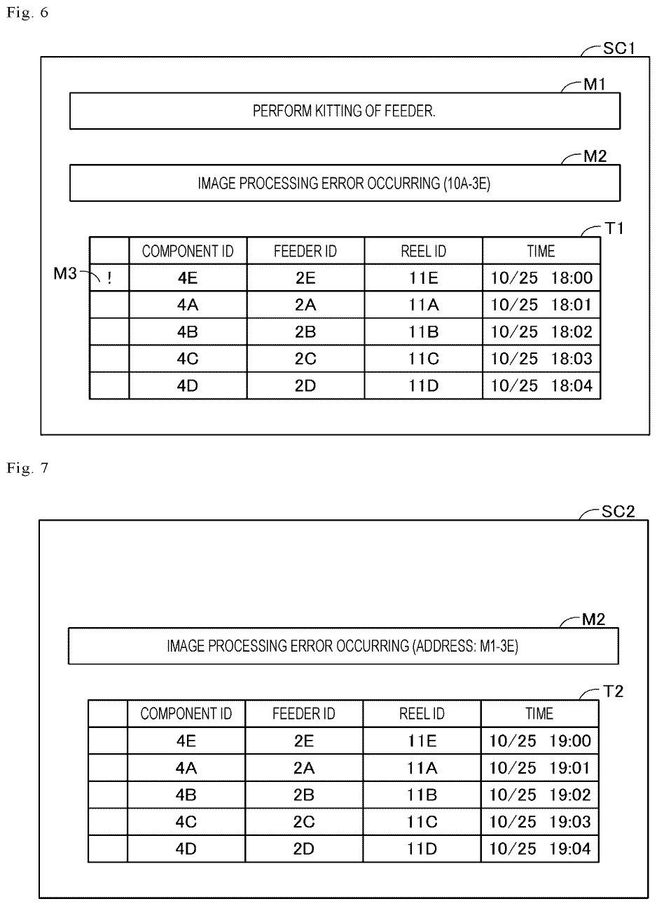

In S30, CPU 54 displays abnormality reporting screen SC1 on display 60. As illustrated in FIG. 6, abnormality reporting screen SC1 includes messages M1 and M2 and ID table T1. Message M1 is a message for prompting the worker to perform kitting of the feeder. Message M2 is a message for reporting to the worker that there is a possibility that an abnormality has occurred in the slot.

Message M2 includes the abnormal mounter ID (for example, 10A) and the abnormal slot ID (for example, 3E) stored in memory 52. Accordingly, CPU 54 can cause the worker who views abnormality reporting screen SC1 to recognize that an abnormality has occurred in the target slot specified by abnormal slot ID in the target component mounter specified by the abnormal mounter ID. In component mounting system 1 of the present example, display 60 of management device 50 is installed in kitting space 70, which is distant from component mounter 10. Therefore, it is difficult for the worker working in kitting space 70 to specify which component mounter 10 among multiple component mounters 10 has an abnormality that has occurred. With management device 50 of the present example, by message M2 including the abnormal mounter ID, the worker located in kitting space 70, which is distant from component mounter 10 in which an abnormality has occurred, can quickly specify component mounter 10 in which an abnormality has occurred.

CPU 54 displays ID table T1 on abnormality reporting screen SC1 in addition to messages M1 and M2. In ID table T1, all component IDs, feeder IDs, and reel IDs corresponding to the abnormal mounter IDs stored in memory 52 are displayed in association with each other. Further, in ID table T1, the time at which the presence or absence of an abnormality is determined for each feeder is displayed.

Further, CPU 54 displays abnormality mark M3 for the feeder ID (for example, 2E) that matches the abnormal feeder ID in memory 52 among the feeder IDs in ID table T1. Accordingly, CPU 54 can cause the worker who views abnormality mark M3 on abnormality reporting screen SC1 to recognize that kitting on the target feeder (for example, feeder 2E) is required. Therefore, for example, it is possible to prevent the worker from mistakenly attaching the target feeder (that is, the feeder requiring kitting) to the slot of another component mounter 10.

Next, in S40, CPU 54 monitors whether the target feeder (feeder requiring kitting) is connected to connector 74 of kitting stand 72. When the target feeder is connected to connector 74, the target feeder transmits connection information including the feeder ID of the target feeder to management device 50 via connector 74. When the connection information is received from connector 74, CPU 54 determines that the target feeder is connected to connector 74 (S40: YES), and proceeds to S42. On the other hand, when the connection information is not received for more than a predetermined time, CPU 54 determines that the target feeder is not connected to connector 74 (S40: NO), skips S42 and S44, and proceeds to S50.

In S42, CPU 54 deletes the abnormal feeder ID from memory 52. That is, assuming that kitting has been performed on the target feeder, the abnormal feeder ID for specifying the target feeder is deleted from memory 52. By deleting the abnormal feeder ID from memory 52 in response to the target feeder being connected to connector 74, it is possible to reliably delete the abnormal feeder ID for identifying the target feeder on which kitting has been performed as compared with a configuration in which the worker manually deletes the abnormal feeder ID.

Next, in S44, CPU 54 deletes message M1 and abnormality mark M3 on abnormality reporting screen SC1 (see FIG. 7). This can cause the worker to recognize that there are no feeders currently requiring kitting. Therefore, for example, even when feeders disposed in kitting space 70 are attached to slots of another component mounter 10, no abnormalities occur in component mounter 10. In addition, even when feeders requiring kitting and feeders not requiring kitting coexist in kitting space 70, the worker can determine which feeder can be attached to another slot by checking abnormality reporting screen SC1.

In S50, CPU 54 monitors that a new feeder is attached to the target slot (that is, the slot to which the target feeder is attached) of the target component mounter (that is, the component mounter in which an abnormality has occurred). When a new feeder is attached to the target slot, the target component mounter transmits the installation information including the feeder ID of the feeder to management device 50. When the installation information is received from the target component mounter, CPU 54 determines that a new feeder is attached to the target slot of the target component mounter (S50: YES), and proceeds to S52. On the other hand, when the installation information is not received for more than a predetermined time, CPU 54 determines that a new feeder is not attached to the target slot (S50: NO), skips S52 and S54, and proceeds to S60.

In S52, CPU 54 deletes the abnormal slot ID from memory 52. That is, in the case of YES in S50, since the work of attaching a new feeder to the target slot is not required, the abnormal slot ID is deleted from memory 52. By deleting the abnormal slot ID from memory 52 in response to a new feeder being attached to the target slot, CPU 54 can reliably delete the abnormal slot ID as compared with a configuration in which the worker manually deletes the abnormal slot ID.

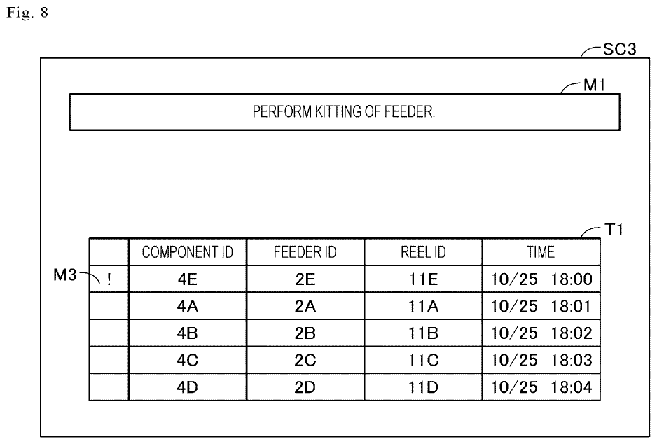

Next, in S54, CPU 54 deletes message M2 on abnormality reporting screen SC1 (see FIG. 8). Accordingly, CPU 54 can cause the worker to recognize that the abnormality of the target slot has been resolved.

In S60, CPU 54 determines whether both the abnormal feeder ID and the abnormal slot ID have been deleted from memory 52. When both have been deleted (S60: YES), CPU 54 returns to S2 and repeats the processing of FIG. 5. When the abnormal feeder ID is deleted and the abnormal slot ID is stored (S60: NO), CPU 54 returns to S50. On the other hand, when the abnormal feeder ID is stored, CPU 54 returns to S40.

When an abnormality occurs in component mounter 10, the target feeder in which an abnormality has occurred is removed from the target slot, and a new feeder is attached to the target slot, thereby resolving the abnormality of component mounter 10. Accordingly, it is possible to continue the mounting of component mounting system 1. However, when the required work is not performed on the target feeder removed from the target slot, the target feeder may be attached to another slot even though there is a cause of an abnormality in the target feeder. In this case, an abnormality may occur again in component mounter 10 to which the target feeder is attached.

### Effects of Present Example

When the abnormality occurrence signal is received from component mounter 10 (S2: YES), management device 50 of component mounting system 1 of the present example generates the abnormal feeder ID and the abnormal slot ID (S10, S20), and stores each ID in memory 52 (S12, S22). When the target feeder is connected to connector 74 (S40: YES), management device 50 deletes the abnormal feeder ID from memory 52 (S42), and when a new feeder is attached to the target slot (S50: YES), deletes the abnormal slot ID from memory 52 (S52). Management device 50 individually manages the abnormal feeder ID and the abnormal slot ID. Therefore, even when a new feeder is attached to the target slot and the abnormal slot ID is deleted from memory 52, the abnormal feeder ID is not deleted from memory 52 unless the target feeder is connected to connector 74. Even when the target feeder is connected to connector 74 and the abnormal feeder ID is deleted from memory 52, the abnormal slot ID is not deleted from memory 52 unless a new feeder is attached to the target slot. Accordingly, for example, management device 50 can prevent the worker from attaching the target feeder whose abnormal feeder ID is stored in memory 52 to another slot. Management device 50 can reduce the occurrence of the abnormalities in component mounter 10.

Points to note regarding the control device described in the example will be described. Although management device 50 of the above-described example manages multiple component mounters 10, management device 50 may manage one component mounter 10. In this case, management device 50 may be included in control device 30 of component mounter 10.

CPU 54 of management device 50 need not display abnormality reporting screen SC1 on display 60 in S30. In other words, the “abnormality information reporting section” can be omitted. In a further modification, for example, control device 30 of the target component mounter may display only message M2 on interface device 24 of the target component mounter, and in this case, message M2 need not include the abnormal component mounter ID. In another modification, CPU 54 may display abnormality reporting screen SC1 including only message M1 on display 60 in S30.

CPU 54 need not execute at least one process of S42 and S52. In this case, for example, when the target feeder is connected to connector 74, CPU 54 may delete only message M1 and abnormality mark M3 from abnormality reporting screen SC1 in a state where the abnormal feeder ID is stored in memory 52.

CPU 54 may monitor the input of information indicating that the repair work of the target feeder has been completed by the worker to management device 50, instead of detecting that the target feeder is connected to connector 74 in S40. In the present modification, the repair work is an example of a “first work”, and management device 50 is an example of an “input section”.

In S10, CPU 54 may generate an abnormal reel ID instead of the abnormal feeder ID. The abnormal reel ID is information for identifying a reel (for example, reel 11D) attached to the target feeder. In this case, CPU 54 stores the abnormal reel ID in memory 52 in S12. Accordingly, CPU 54 can specify the target feeder by the abnormal reel ID. In the present modification, the abnormal reel ID is an example of “first identification information”.

### Correspondence Relationship

Tape feeders 2A to 2E are examples of “multiple component supply devices”. Slots 3A to 3E are examples of “multiple installation positions”. Management device 50 is an example of an “abnormality management device” and an “abnormality reporting device”. Suction nozzle 6 not holding electronic components 4A to 4D in proper orientation is an example of “specific abnormality”. Memory 52 is an example of an “abnormality information storage section”. The abnormal feeder ID and the abnormal slot ID are examples of “first abnormality information” and “second abnormality information”, respectively. The connection of the target feeder to connector 74 and the attachment of a new feeder to the target slot are examples of “first work” and “second work”, respectively. Connector 74 is an example of an “input section”.

The processes of S10 and S20 of FIG. 5 are examples of processes executed by the “abnormality information generation section”. The processes of S42 and S52 are examples of processes executed by the “abnormality information deletion section”. The process of S30 is an example of the process executed by the “abnormality information reporting section”.

The technical elements described in the present description or the drawings exhibit technical usefulness independently or in various combinations and are not limited to the combinations described in the claims as originally filed. In addition, the technique described in the present description or the drawings simultaneously achieves multiple purposes, and has technical usefulness with achieving one purpose itself of the multiple purposes.

### REFERENCE SIGNS LIST

1: component mounting system
5: circuit board
2A, 2B, 2C, 2D, 2E: tape feeder
3A, 3B, 3C, 3D, 3E: slot
4A, 4B, 4C, 4D, 4E: electronic component
6: suction nozzle
10: component mounter
11D: reel
12: feeder unit
13D: tape
14: feeder holding section
15: imaging device
16: mounting head
18: head moving device
20: board conveyor
22: component mounting section
24: interface device
30: control device
32, 52: memory
34, 54: CPU
50: management device
55: abnormality information generation section
56: abnormality information deletion section
57: abnormality information reporting section
58: connector connection detection section
60: display
70: kitting space
72: kitting stand
74: connector
100: component mounting line

1. An abnormality management device for managing abnormalities occurring in a component mounter including multiple component supply devices and multiple installation positions where the multiple component supply devices are detachably attached, the abnormality management device comprising:
an abnormality information generation section configured to, when a specific abnormality has occurred in the component mounter, generate first abnormality information indicating that an abnormality has occurred in a specific component supply device that is a component supply device related to the specific abnormality and second abnormality information indicating that an abnormality has occurred at a specific installation position where the specific component supply device has been attached;
an abnormality information storage section configured to store the first abnormality information and the second abnormality information generated by the abnormality information generation section; and
an abnormality information deletion section configured to,
when first work for resolving the abnormality is performed on the specific component supply device in which the abnormality has occurred, delete the first abnormality information generated by the abnormality information generation section from the abnormality information storage section, and
when second work for resolving the abnormality is performed at the specific installation position where the abnormality has occurred, delete the second abnormality information generated by the abnormality information generation section from the abnormality information storage section.

2. The abnormality management device according to claim 1, further comprising:
an abnormality information reporting section configured to, when at least one of the first abnormality information and the second abnormality information is stored in the abnormality information storage section, report at least one of the first abnormality information and the second abnormality information stored in the abnormality information storage section to a worker.

3. The abnormality management device according to claim 2,
wherein the deletion of the first abnormality information by the abnormality information deletion section is performed by deleting the first abnormality information stored in the abnormality information storage section from the abnormality information storage section, and
the deletion of the second abnormality information by the abnormality information deletion section is performed by deleting the second abnormality information stored in the abnormality information storage section from the abnormality information storage section.

4. The abnormality management device according to claim 1,
wherein the second work includes
removing the specific component supply device from the specific installation position where the specific abnormality has occurred, and
attaching a new component supply device to the specific installation position after the specific component supply device is removed from the specific installation position.

5. The abnormality management device according to claim 1, further comprising:
an input section configured to receive that the first work has been performed,
wherein the abnormality information deletion section deletes the first abnormality information generated by the abnormality information generation section when the input section receives an input indicating that the first work is to be performed.

6. The abnormality management device according to claim 1,
wherein the first abnormality information includes first identification information for identifying the specific component supply device in which the specific abnormality has occurred, and
the second abnormality information includes second identification information for identifying the specific installation position where the specific abnormality has occurred.

7. A component mounting system comprising:
multiple component supply devices;
multiple component mounters including multiple installation positions where the multiple component supply devices are detachably attached; and
the abnormality management device according to claim 1 configured to manage the abnormalities occurring in the multiple component mounters.

8. An abnormality reporting device for reporting abnormalities occurring in a component mounter including multiple component supply devices and multiple installation positions where the multiple component supply devices are detachably attached, the abnormality reporting device comprising:
an abnormality information generation section configured to, when a specific abnormality related to any of the component supply devices has occurred in the component mounter, generate first abnormality information indicating that an abnormality has occurred in a specific component supply device that is a component supply device related to the specific abnormality and second abnormality information indicating that an abnormality has occurred at a specific installation position where the specific component supply device is attached; and
an abnormality information reporting section configured to report two pieces of abnormality information of the generated first abnormality information and second abnormality information to a worker.
